(19) United States
(12) Patent Application Publication
(10) Pub. No.: US 2026/0324397 A1
(43) Pub. Date: Oct. 15, 2026

(54) SEMICONDUCTOR STRUCTURE AND METHOD OF FORMING SAME

(71) Applicant: Tokyo Electron Limited, Tokyo (JP)

(72) Inventor: Kandabara Tapily, Albany, NY (US)

(21) Appl. No.: 19/177,073

(22) Filed: Apr. 11, 2025

(51) Int. Cl. H01L 23/528; H01L 21/768; H01L 23/532

(52) U.S. Cl. CPC H10W 20/43; H10W 20/035; H10W 20/056; H10W 20/069; H10W 20/081; H10W 20/435; H10W 20/4403

(57) ABSTRACT

A semiconductor device includes a dielectric layer over a substrate and a conductive feature embedded in the dielectric layer. The conductive feature includes a conductive material and a barrier layer extending along a sidewall of the conductive material. The barrier layer includes a first material. The conductive feature further includes a liner extending along a bottom of the conductive material. The liner includes a second material different from the first material.

### TECHNICAL FIELD

The present disclosure relates generally to methods of processing a substrate, and, in particular embodiments, to a semiconductor structure and a method of forming the same.

### BACKGROUND

Semiconductor devices have undergone continuous miniaturization over the past several decades, enabling higher performance, lower power consumption, and increased functionality. This scaling trend has led to increasingly complex fabrication processes, particularly for interconnect structures that provide electrical connections between transistors and other components on a chip. As device dimensions continue to shrink, the width and spacing of interconnect lines have decreased accordingly, with current advanced nodes featuring interconnect pitches in the range of tens of nanometers.

Copper has become the predominant metal used for interconnects due to its low resistivity, typically formed using a damascene process where trenches and vias are etched into a dielectric material, lined with a barrier layer, filled with copper, and then planarized. However, at reduced dimensions, the proportion of the interconnect cross-section occupied by the barrier layer becomes significant, reducing the volume available for the conductive material and thereby increasing the effective resistance of the interconnect. Traditional barrier materials such as tantalum, tantalum nitride, and titanium nitride require a minimum thickness to maintain their barrier properties, which becomes problematic as dimensions scale down.

Another challenge in advanced interconnect fabrication is alignment between successive metal layers, where misalignment can lead to increased contact resistance, reduced yield, and reliability issues. Conventional lithography-based alignment methods face increasing difficulties as dimensions shrink, leading to the need for self-aligned processes.

### SUMMARY

In accordance with an embodiment, a semiconductor device includes: a dielectric layer over a substrate; and a conductive feature embedded in the dielectric layer, the conductive feature including: a conductive material; a barrier layer extending along a sidewall of the conductive material, the barrier layer including a first material; and a liner extending along a bottom of the conductive material, the liner including a second material different from the first material.

In accordance with another embodiment, A method includes: forming a first dielectric layer over a substrate; forming a first recess and a second recess in the first dielectric layer; forming a liner on bottoms of the first recess and the second recess; filling the first recess and the second recesses with a conductive material; forming a first hard mask feature over the conductive material in the first recess; forming a second hard mask feature over the conductive material in the second recess; selectively removing the first dielectric layer to form a third recesses, the third recesses being interposed between the first hard mask feature and the second hard mask feature; forming a barrier layer on sidewalls of the conductive material; forming a second dielectric layer over the conductive material, the second dielectric layer overfilling the third recess; exposing the first hard mask feature and the second hard mask feature; and selectively removing the first hard mask feature and the second hard mask feature to form a fourth recess and a fifth recess in the second dielectric layer.

In accordance with yet another embodiment, a method includes: depositing a first dielectric material over a substrate; patterning the first dielectric material to form a plurality of first recesses in the first dielectric material; depositing a first conductive material on bottoms of the plurality of first recesses; filling the plurality of first recesses with a second conductive material; forming a plurality of hard mask features over the second conductive material; selectively removing the first dielectric material to form a plurality of second recesses; forming a barrier layer on sidewalls of the second conductive material; depositing a second dielectric material over the second conductive material, the second dielectric material overfilling the plurality of second recesses; removing a portion of second dielectric material to expose the plurality of hard mask features; and selectively removing the plurality of hard mask features to form a plurality of third recesses in the second dielectric material.

### BRIEF DESCRIPTION OF THE DRAWINGS

For a more complete understanding of the present disclosure, and the advantages thereof, reference is now made to the following descriptions taken in conjunction with the accompanying drawings, in which:

FIGS. 1A-1M illustrate cross-sectional views of intermediate stages in the manufacturing of a semiconductor structure, in accordance with various embodiments;

FIG. 2 illustrates a cross-sectional view of a semiconductor structure, in accordance with various embodiments;

FIG. 3 illustrates a cross-sectional view of a semiconductor structure, in accordance with various embodiments;

FIG. 4 illustrates a cross-sectional view of a semiconductor structure, in accordance with various embodiments;

FIGS. 5A-5L illustrate cross-sectional views of intermediate stages in the manufacturing of a semiconductor structure, in accordance with various embodiments;

FIG. 6 illustrates a cross-sectional view of a semiconductor structure, in accordance with various embodiments;

FIG. 7 illustrates a cross-sectional view of a semiconductor structure, in accordance with various embodiments;

FIG. 8 illustrates a cross-sectional view of a semiconductor structure, in accordance with various embodiments; and

FIGS. 9A and 9B illustrate a flow diagram of a method for forming a semiconductor structure, in accordance with various embodiments.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

Embodiments of the present disclosure provide novel semiconductor structures and fabrication methods that address challenges associated with interconnect scaling. The approaches described herein enable the formation of self-aligned interconnect structures with reduced resistance while maintaining barrier integrity, even at extremely small dimensions. In various embodiments, a semiconductor structure includes a conductive feature with different materials for the sidewall barrier and bottom liner, allowing optimization of both vertical and lateral electrical characteristics while maintaining reliable diffusion barrier properties.

In one or more embodiments, a method for forming interconnect structures includes depositing a conformal liner in recesses formed in a first dielectric layer, filling the recesses with a conductive material, and forming hard mask features over the conductive material. The first dielectric material is then selectively removed, exposing the sidewalls of the conductive material. A barrier layer can be formed on these sidewalls either by converting a portion of the existing liner or by replacing it with a new barrier material. In various embodiments, this approach enables the use of ultra-thin barrier materials, such as two-dimensional materials, which can maintain barrier properties at thicknesses below 1 nanometer while allowing for increased volume of the conductive material.

The methods described herein provide self-alignment for subsequent metal layers without requiring precise lithography alignment, as the hard mask features create natural recesses in the second dielectric layer after their removal. This self-alignment capability can significantly improve yield and reliability in advanced technology nodes. Additionally, the ability to select different materials for sidewall barriers and bottom liners allows for optimization of both lateral diffusion barrier properties and vertical contact resistance. In various embodiments, air gaps may be incorporated between adjacent conductive features to further reduce capacitance. The flexibility to incorporate various materials, including transition metals, binary alloys, ternary compounds, and two-dimensional materials, provides a versatile platform for addressing interconnect challenges across multiple technology generations. These and additional details are further discussed below.

While the various embodiments are described primarily in the context of semiconductor interconnect structures for logic devices, it should also be appreciated that these embodiments may also apply to memory devices, power devices, and analog/mixed-signal integrated circuits. In particular, aspects of this disclosure may similarly apply to advanced packaging technologies, through-silicon vias (TSVs), interposers, fan-out wafer level packaging, and other applications requiring fine-pitch metal structures with low resistance and precise alignment.

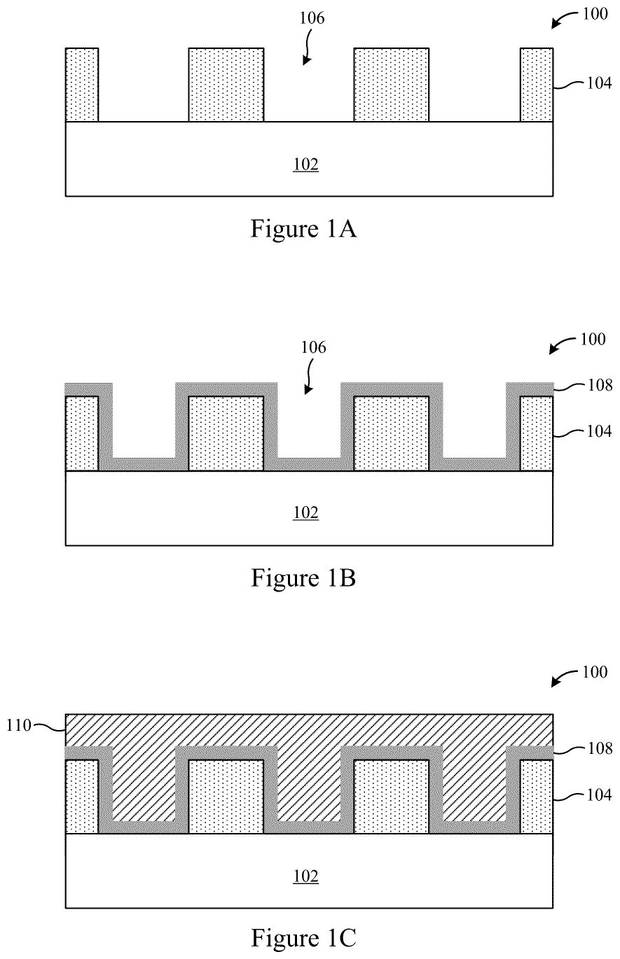

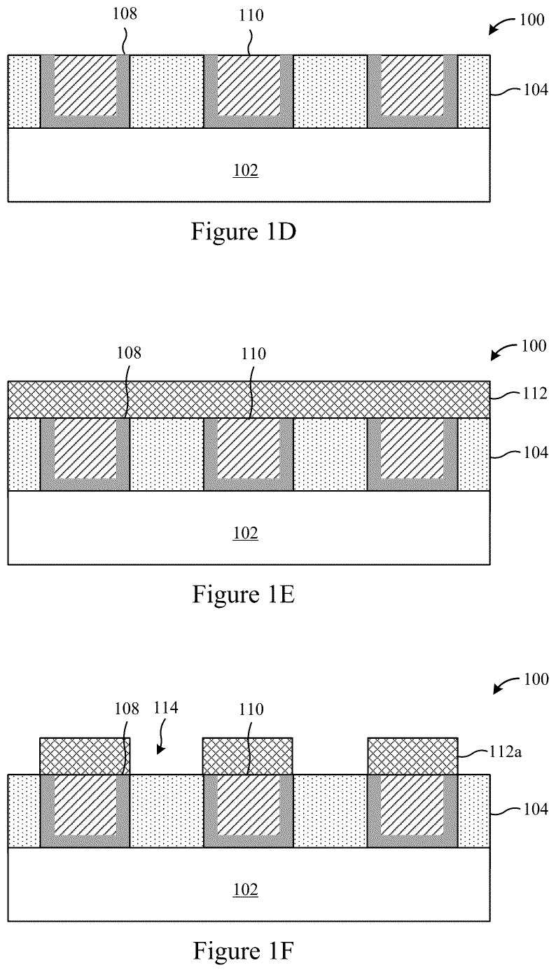

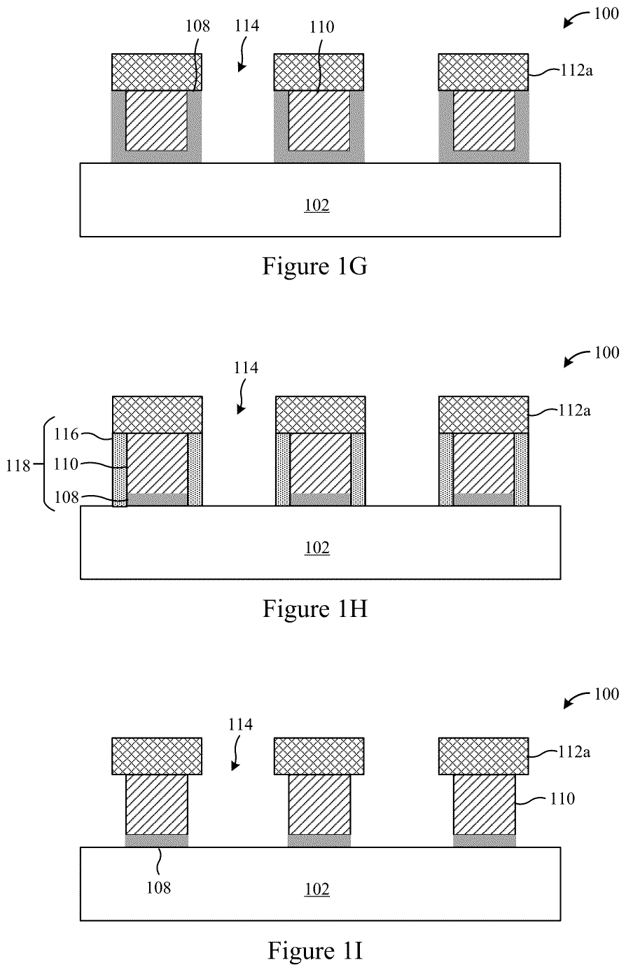

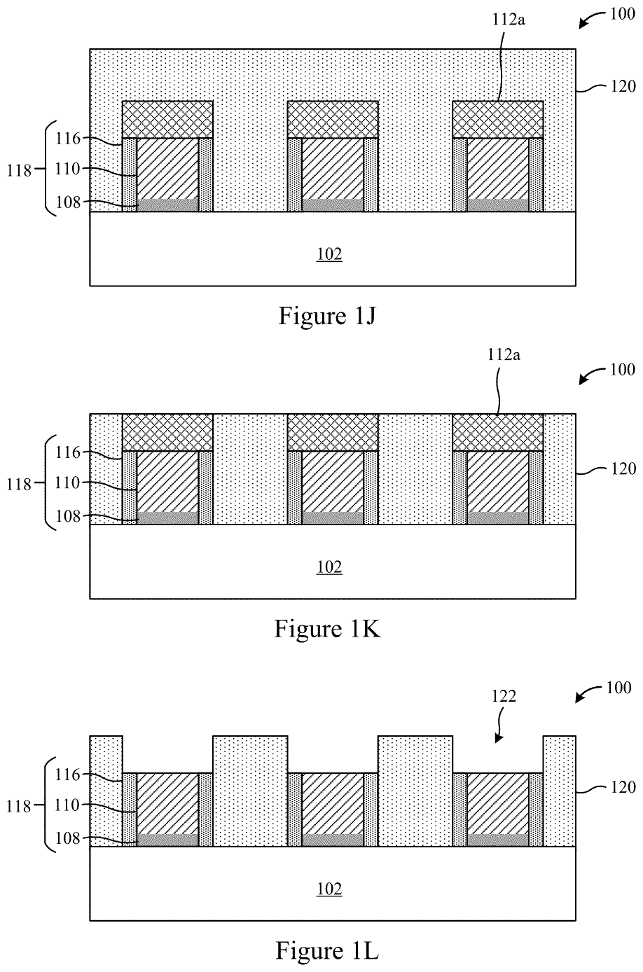

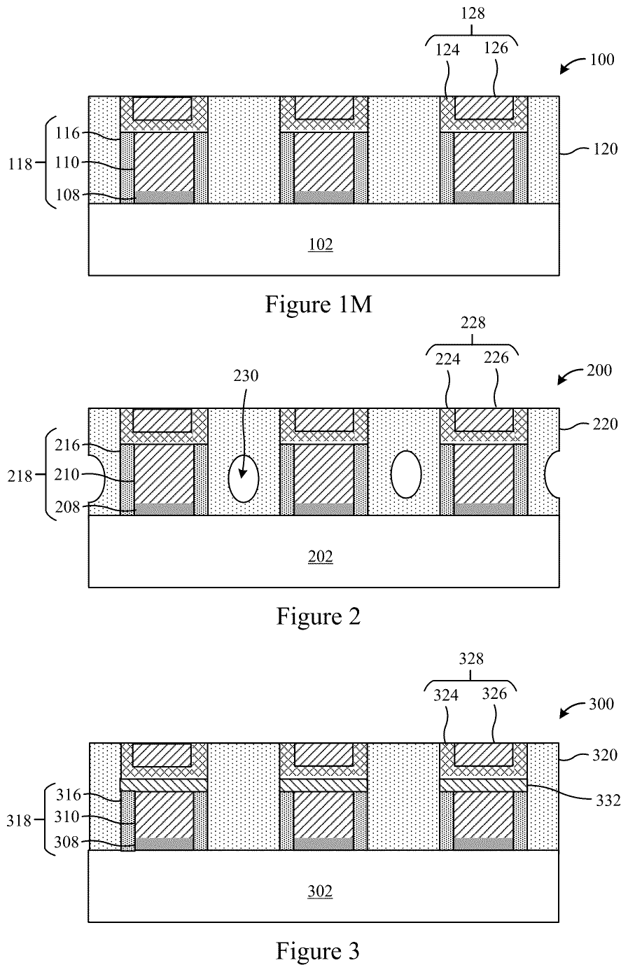

FIGS. 1A-1M illustrate cross-sectional views of intermediate stages in the manufacturing of a semiconductor structure 100, in accordance with various embodiments. Referring to FIG. 1A, the semiconductor structure 100 includes a substrate 102 with a dielectric layer 104 formed thereon. The dielectric layer 104 has openings 106 formed therein. In some embodiments, the substrate 102 may include a semiconductor material such as silicon, silicon germanium, silicon carbide, gallium arsenide, or other suitable semiconductor materials. In other embodiments, substrate 102 may comprise heterogeneous layers such as silicon germanium on silicon, gallium nitride on silicon, silicon carbon on silicon, or layers of silicon on a silicon or silicon-on-insulator (SOI) substrate. In various embodiments, the substrate 102 may include previously formed device structures such as transistors, capacitors, resistors, or other circuit elements formed during front-end-of-line (FEOL) processing.

The dielectric layer 104 may be formed over the substrate 102 using deposition techniques such as chemical vapor deposition (CVD), physical vapor deposition (PVD), atomic layer deposition (ALD), spin-on deposition, other suitable deposition methods, combinations thereof, or the like. In some embodiments, the dielectric layer 104 may comprise silicon oxide, silicon nitride, silicon oxynitride, silicon carbide, silicon oxycarbide, or a low-k dielectric material having a dielectric constant less than that of silicon dioxide. For advanced technology nodes, the dielectric layer 104 may comprise an ultra-low-k dielectric material with a dielectric constant below 2.5.

The openings 106 in the dielectric layer 104 may be formed using suitable photolithography and etching processes. These openings 106 define the locations where conductive features (e.g., conductive features 118 illustrated in FIG. 1M) will be formed in subsequent processing steps. The openings 106 may have various shapes and dimensions depending on the specific design requirements. In advanced technology nodes, the openings 106 may have critical dimensions in the nanometer range, with high aspect ratios that present challenges for subsequent filling processes. The pattern of the openings 106 establishes the foundation for the interconnect structure that will provide electrical connections between various components of the integrated circuit formed on the substrate 102.

Referring to FIG. 1B, a liner layer 108 is blanket deposited over the dielectric layer 104 and along the sidewalls and bottoms of the openings 106. The liner layer 108 serves as a foundation for subsequent metal deposition and may provide barrier properties to prevent diffusion of the conductive material into the surrounding dielectric material of the dielectric layer 104. In some embodiments, the liner layer 108 is deposited as a conformal layer.

In various embodiments, the liner layer 108 may comprise materials such as tantalum, molybdenum, tungsten, tantalum nitride, ruthenium, hafnium, cobalt, other suitable liner materials, combinations thereof, or the like. The liner layer 108 may be deposited using techniques such as ALD, CVD, PVD, or other suitable deposition methods that provide good step coverage to ensure uniform coating along the sidewalls and bottoms of the openings 106. The thickness of the liner layer 108 may be controlled to balance barrier properties with the available volume for subsequent conductive material filling. In an embodiment, the thickness of the liner layer 108 may be in a range from 0.5 nm to 3 nm.

In some embodiments, the liner layer 108 may be selectively deposited on specific surfaces of the openings 106, such as only on the sidewalls, only on the bottoms, or on both sidewalls and bottoms but not on the top surface of the dielectric layer 104. Selective deposition can reduce subsequent processing steps by eliminating the need to remove excess liner material from the top surface during planarization. The liner layer 108 provides a low vertical resistance interface for the conductive material that will be deposited in a subsequent step, which allows for maintaining good electrical performance in advanced technology nodes with small feature sizes.

Referring to FIG. 1C, a conductive layer 110 is formed over the liner layer 108. The conductive layer 110 fills the openings 106 in the dielectric layer 104, with the liner layer 108 positioned between the conductive layer 110 and the dielectric layer 104. The conductive layer 110 forms the main current-carrying portion of the interconnect structure. In various embodiments, the conductive layer 110 may comprise materials such as copper, cobalt, ruthenium, molybdenum, tungsten, nickel, nickel-aluminum alloys, copper-aluminum alloys, or other suitable conductive materials including ternary compounds or MAX phase materials. The selection of the conductive material may depend on factors such as resistivity, electromigration resistance, and compatibility with surrounding materials. The conductive layer 110 may be deposited using techniques such as electroplating, electroless plating, CVD, PVD, combinations thereof, or other suitable deposition methods capable of filling the openings 106 with minimal voids or seams.

In some embodiments, the conductive layer 110 may overfill the openings 106, creating a continuous layer over the top surface of the dielectric layer 104. This excess material will be removed in a subsequent planarization step to form isolated conductive features. The combination of the liner layer 108 and conductive layer 110 within the openings 106 (see FIG. 1A) forms the basis for the interconnect structures that will provide electrical connections within the semiconductor structure 100.

Referring to FIG. 1D, a planarization process may be performed to remove excess portions of the conductive layer 110 and liner layer 108 from the top surface of the dielectric layer 104. The planarization process creates isolated conductive features within the openings 106, with each feature comprising the conductive layer 110 and the underlying liner layer 108. After performing the planarization process, top surfaces of the conductive layer 110, liner layer 108, and dielectric layer 104 are substantially coplanar or level within process variations of the planarization process.

The planarization process may be performed using chemical mechanical polishing (CMP), which combines chemical etching and mechanical abrasion to achieve a planar surface. The CMP process may be optimized with specific slurries and process parameters to ensure uniform material removal across the wafer while minimizing dishing or erosion of the conductive features. In various embodiments, the planarization may be performed in multiple steps with different slurries tailored for the specific materials being removed.

After planarization, the conductive layer 110 remains only within the openings 106 (see FIG. 1A), forming conductive features that are electrically isolated from each other by the surrounding dielectric layer 104. The liner layer 108 remains along the sidewalls and bottom of each conductive feature, providing an interface between the conductive layer 110 and the dielectric layer 104. This planarized structure serves as the foundation for subsequent processing steps that will create self-aligned features, as will be shown in the following figures. The planar surface also allows for accurate lithography for subsequent patterning steps.

Referring to FIG. 1E, a mask layer 112 is formed over the planarized surface of the structure shown in FIG. 1D. The mask layer 112 may be deposited as a continuous layer covering the top surfaces of the conductive layer 110 and the dielectric layer 104. This mask layer 112 will serve as a hard mask for subsequent processing steps to enable the self-alignment feature of the disclosed approach.

In various embodiments, the mask layer 112 may comprise materials such as silicon nitride, silicon carbonitride, boron nitride, aluminum oxide, or other suitable hard mask materials that provide desired selectivity during subsequent etching processes. The thickness of the mask layer 112 may be controlled based on the desired depth of self-aligned features to be formed in later steps and the etch selectivity between the mask material and the underlying materials. The mask layer 112 may be deposited using techniques such as CVD, ALD, a combination thereof, or the like. In an embodiment, the thickness of the mask layer 112 may be 15 nm or less.

In other embodiments, the mask layer 112 may be selectively deposited only on the conductive layer 110 and not on the dielectric layer 104. Such selective deposition can simplify subsequent processing by eliminating the need for a separate patterning step. The selective deposition may be achieved through techniques that exploit differences in surface properties between the conductive layer 110 and the dielectric layer 104, such as selective chemical vapor deposition, area-selective atomic layer deposition, or the like.

Referring to FIG. 1F, the mask layer 112 is patterned to form patterned mask features 112a and openings 114. The patterning process removes portions of the mask layer 112 that were covering the dielectric layer 104 while leaving the portions covering the conductive layer 110 intact. This creates the patterned mask features 112a that are aligned with the underlying conductive features formed by the conductive layer 110 and liner layer 108, and openings 114 that expose portions of the dielectric layer 104 between adjacent conductive features.

The patterning of the mask layer 112 may be performed using suitable lithography and etching processes. In various embodiments, a photoresist layer may be applied over the mask layer 112, exposed to a pattern of radiation through a photomask, and developed to create a pattern in the photoresist. This pattern is then transferred to the mask layer 112 through an etching process such as reactive ion etching (RIE), which selectively removes portions of the mask layer 112 not protected by the photoresist.

The openings 114 define the regions where the dielectric layer 104 will be selectively removed in subsequent processing steps. The width of the openings 114 may be controlled through the lithography and etching processes to achieve the desired spacing between adjacent conductive features. In an embodiment, the patterning may be performed with a slight overlay tolerance, as the self-alignment mechanism of the disclosed approach can accommodate minor misalignments. The patterned mask features 112a will serve as protective caps for the underlying conductive features during subsequent processing steps, while the openings 114 provide access for the selective removal of the dielectric layer 104.

Referring to FIG. 1G, the dielectric layer 104 is selectively removed through the openings 114. The selective removal process extends the openings 114 into the regions previously occupied by the dielectric layer 104, exposing portions of the liner layer 108 formed on the sidewalls of the conductive layer 110. The patterned mask features 112a protect the top surfaces of the liner layer 108 and the conductive layer 110 during the removal process.

The selective removal of the dielectric layer 104 may be performed using a wet etching process, a dry etching process, a combination thereof, or the like. In various embodiments, the etching chemistry is selected to provide high selectivity between the dielectric layer 104 and the surrounding materials, including the liner layer 108, conductive layer 110, and patterned mask features 112a. This high selectivity ensures that only the dielectric material of the dielectric layer 104 is removed while the other materials remain substantially intact. For example, if the dielectric layer 104 comprises silicon dioxide, a buffered oxide etch or a fluorine-based plasma etch may be used for selective removal. The exposed portions of the liner layer 108 within the openings 114 provide access for subsequent processing steps, which may include conversion of the liner material or its replacement with a different barrier material as described below in greater detail.

Referring to FIG. 1H, the exposed portions of the liner layer 108 are converted into a barrier layer 116. The conversion process transforms the material composition of the exposed portions of the liner layer 108 while leaving the unexposed portions of the liner layer 108 substantially unchanged. The patterned mask features 112a protect the top surfaces of the liner layer 108 and the conductive layer 110 during the conversion process.

In various embodiments, the conversion of the liner layer 108 into the barrier layer 116 may be performed using gas-phase reactions, plasma treatments, thermal treatments, or other suitable processes that can modify the chemical composition of the liner material. In some embodiments when the liner layer 108 comprises a transition metal (e.g., Ta, Mo, Nb, Hf, Zr, or the like), the conversion process may involve exposure to a chalcogenide (e.g., S, Se, or Te) containing gas to form a two-dimensional (2D) transition metal dichalcogenide. In other embodiments, the metal of the liner layer 108 may be exposed to phosphorus, oxygen, or nitrogen-containing gases to form a metal phosphide, a metal oxide, or a metal nitride, respectively. For example, if the liner layer 108 comprises tantalum, the conversion process may involve exposure to sulfur, selenium, tellurium, phosphorus, oxygen, or nitrogen-containing gases to form tantalum sulfide, tantalum selenide, tantalum telluride, tantalum phosphide, tantalum oxide, or tantalum nitride, respectively. These converted materials may exhibit enhanced barrier properties compared to the original liner material, particularly at reduced thicknesses. In an embodiment, the liner layer 108 is less electrically resistive than the barrier layer 116.

The conversion process is particularly advantageous for forming ultra-thin barrier layers, such as 2D materials, which can maintain excellent barrier properties at thicknesses below 1 nanometer. In an embodiment, the suitable 2D materials may include 2D transition metal dichalcogenides having chemical formulas MS₂, MTe₂, MSe₂, or the like, where M represents transition metals such as Ta, Mo, Nb, Hf, Zr, or the like. The conversion may be controlled to achieve a specific thickness or composition of the barrier layer 116. In an embodiment, the thickness of the barrier layer 116 may be in a range from 0.5 nm to 2 nm. In some embodiments, the thickness of the barrier layer 116 may be different from the thickness of the liner layer 108. In one embodiment, the thickness of the barrier layer 116 is less than the thickness of the liner layer 108. In another embodiment, the thickness of the barrier layer 116 is greater than the thickness of the liner layer 108.

The bottom portions of the liner layer 108 remain unconverted, maintaining their original composition and providing low vertical resistance between the conductive layer 110 and underlying structures. This dual-material configuration allows both the barrier properties along the sidewalls of the conductive layer 110 and the electrical conductivity at the bottom interfaces of the conductive layer 110. The conductive layer 110, in combination with the barrier layer 116 and remaining unconverted portions of the liner layer 108, forms a plurality of conductive features 118 over the substrate 102. The conductive features 118 may be conductive lines, conductive vias, or a combination thereof.

Referring to FIG. 1I, in other embodiments, the exposed portions of the liner layer 108 (see FIG. 1G) are removed and the barrier layer 116 is subsequently deposited on exposed sidewalls of the conductive layer 110 to form the structure illustrated in FIG. 1H. This replacement approach involves selectively etching away the exposed portions of the liner layer 108 while leaving the bottom portions of the liner layer 108 intact, followed by deposition of a new barrier material to form the barrier layer 116. The patterned mask features 112a protect the top surface of the conductive layer 110 during these processes.

The removal of the exposed portions of the liner layer 108 may be performed using a selective etching process that has high selectivity to the liner material compared to the conductive layer 110 and the patterned mask features 112a. In various embodiments, this selective etching may be accomplished using wet chemical etching, reactive ion etching, or other suitable etching techniques.

After removal of the exposed portions of liner layer 108, the barrier layer 116 is deposited along the exposed sidewalls of the conductive layer 110. The barrier layer 116 may be deposited using techniques such as ALD, CVD, PVD, combinations thereof, or the like. This replacement approach allows for the selection of a desired barrier material that may differ from the original liner material, enabling enhanced barrier properties while maintaining the benefits of the original liner material at the bottom surface of the conductive layer 110 for low vertical resistance.

Referring to FIG. 1J, a dielectric layer 120 is formed over the structure shown in FIG. 1H. The dielectric layer 120 fills the openings 114 (see FIG. 1H) and covers the barrier layer 116, which lines the sidewalls of the conductive layer 110. In some embodiments, the dielectric layer 120 overfills the openings 114 and covers top surfaces of the patterned mask features 112a.

The dielectric layer 120 may be deposited using techniques such as CVD, plasma-enhanced chemical vapor deposition (PECVD), ALD, spin-on deposition, combinations thereof, or the like. In some embodiments, the dielectric layer 120 may comprise silicon oxide, silicon nitride, silicon oxynitride, silicon carbide, silicon oxycarbide, or a low-k dielectric material having a dielectric constant less than that of silicon dioxide. For advanced technology nodes, the dielectric layer 120 may comprise an ultra-low-k dielectric material with a dielectric constant below 2.5.

In some embodiments, the deposition of the dielectric layer 120 may be performed in multiple steps or with specific process conditions to ensure complete filling of the openings 114 (see FIG. 1H) without voids or seams. The dielectric layer 120 provides electrical isolation between the conductive features 118 and forms the foundation for subsequent interconnect layers. Unlike the dielectric layer 104 (see FIG. 1A), which was removed in previous steps, the dielectric layer 120 can be selected specifically for its electrical and mechanical properties without being constrained by compatibility with the initial fabrication steps. This flexibility in material selection allows for optimization of the dielectric properties in the final structure.

Referring to FIG. 1K, a planarization process is performed on the dielectric layer 120 to expose the top surfaces of the patterned mask features 112a. The planarization process creates a planar surface where the top surfaces of the patterned mask features 112a and the remaining portions of the dielectric layer 120 are substantially coplanar or level within process variations of the planarization process.

The planarization process may be performed using CMP, which combines chemical etching and mechanical abrasion to achieve a planar surface. The CMP process may be optimized with specific slurries and process parameters to ensure uniform material removal across the wafer while providing good selectivity between the dielectric layer 120 and the patterned mask features 112a. This planarized structure provides a foundation for the subsequent removal of the patterned mask features 112a, which will create recesses for forming self-aligned conductive features in the next interconnect layer. The planar surface also allows for accurate lithography for any additional patterning steps that may be needed.

Referring to FIG. 1L, the patterned mask features 112a are selectively removed creating openings 122 in the dielectric layer 120. The openings 122 are self-aligned with the underlying conductive features 118. In some embodiments, the selective removal process leaves the dielectric layer 120 intact while completely removing the patterned mask features 112a. The selective removal of the patterned mask features 112a may be performed using a wet etching process, a dry etching process, a combination thereof, or the like. In various embodiments, the etching chemistry is selected to provide high selectivity between the mask material and the surrounding materials, including the conductive layer 110, the barrier layer 116, and the dielectric layer 120. For example, if the patterned mask features 112a comprise silicon nitride, a phosphoric acid-based wet etch or a selective plasma etch may be used for the selective removal process.

The openings 122 created by the removal of the patterned mask features 112a serve as self-aligned recesses for subsequent formation of conductive features in the next interconnect layer. This self-alignment mechanism allows for eliminating the need for precise lithographic alignment between successive interconnect layers. The dimensions of the openings 122, particularly their depth, are determined by the original thickness of the patterned mask features 112a (see FIG. 1K), which can be controlled during the earlier deposition process. The self-aligned openings 122 allow for improved contact between the current interconnect layer and the next layer to be formed, reducing contact resistance and improving overall device performance.

Referring to FIG. 1M, conductive features 128 are formed in the openings 122 (see FIG. 1L). The conductive features 128 include a barrier layer 124 lining the sidewalls and bottom of each opening 122, and a conductive layer 126 filling the remaining volume of each opening 122. The conductive features 128 provide electrical connections to the underlying conductive features 118.

The barrier layer 124 may be deposited using techniques such as ALD, CVD, PVD, combinations thereof, or the like. In various embodiments, the barrier layer 124 may comprise materials such as tantalum, tantalum nitride, titanium, titanium nitride, or other suitable barrier materials that prevent diffusion of the conductive material into the surrounding dielectric. The thickness of the barrier layer 124 may be optimized to provide sufficient barrier properties while maximizing the volume available for the conductive layer 126.

The conductive layer 126 is deposited over the barrier layer 124, filling the remaining volume of the openings 122. In various embodiments, the conductive layer 126 may comprise materials such as copper, cobalt, ruthenium, tungsten, or other suitable conductive materials. The conductive layer 126 may be deposited using techniques such as electroplating, electroless plating, CVD, PVD, combinations thereof, or the like. After the deposition, a planarization process such as CMP may be performed to remove excess material and create isolated conductive features 128.

FIG. 2 illustrates a cross-sectional view of a semiconductor structure 200, in accordance with various embodiments. Unless otherwise indicated, features 2xx of FIG. 2 may be similar to features 1xx of FIG. 1M, may be formed using materials and methods that are similar to those described above with reference to FIGS. 1A-1M, and descriptions of the similar features are not repeated herein.

The semiconductor structure 200 represents a variation of the structure shown in FIG. 1M, with the addition of an air gap 230 between adjacent conductive features 218. The air gap 230 is formed in the dielectric layer 220 between adjacent conductive features 118, replacing a portion of the solid dielectric material of the dielectric layer 220 with air or another gas having a lower dielectric constant. In various embodiments, the air gap 230 may be formed through selective removal of a sacrificial material, controlled deposition techniques that create voids, or other suitable methods. The presence of the air gap 230 reduces the effective dielectric constant of the material surrounding the conductive features 218, thereby decreasing parasitic capacitance between adjacent conductive features 218.

FIG. 3 illustrates a cross-sectional view of a semiconductor structure 300, in accordance with various embodiments. Unless otherwise indicated, features 3xx of FIG. 3 may be similar to features 1xx of FIG. 1M, may be formed using materials and methods that are similar to those described above with reference to FIGS. 1A-1M, and descriptions of the similar features are not repeated herein.

The semiconductor structure 300 represents a variation of the structure shown in FIG. 1M, with the addition of a capping layer 332 on top of the conductive features 318. The capping layer 332 may be selectively formed on the top surface of the conductive features 318, providing protection against oxidation, electromigration, and other reliability concerns. In some embodiments, the capping layer 332 may be formed before forming a mask layer over the conductive features 318 (see FIGS. 1D and 1E). In various embodiments, the capping layer 332 may comprise materials such as cobalt, ruthenium, tantalum, or other suitable metals or alloys that can enhance the reliability of the conductive features 318. The capping layer 332 may be formed using selective deposition techniques such as electroless plating, selective CVD, a combination thereof, or the like.

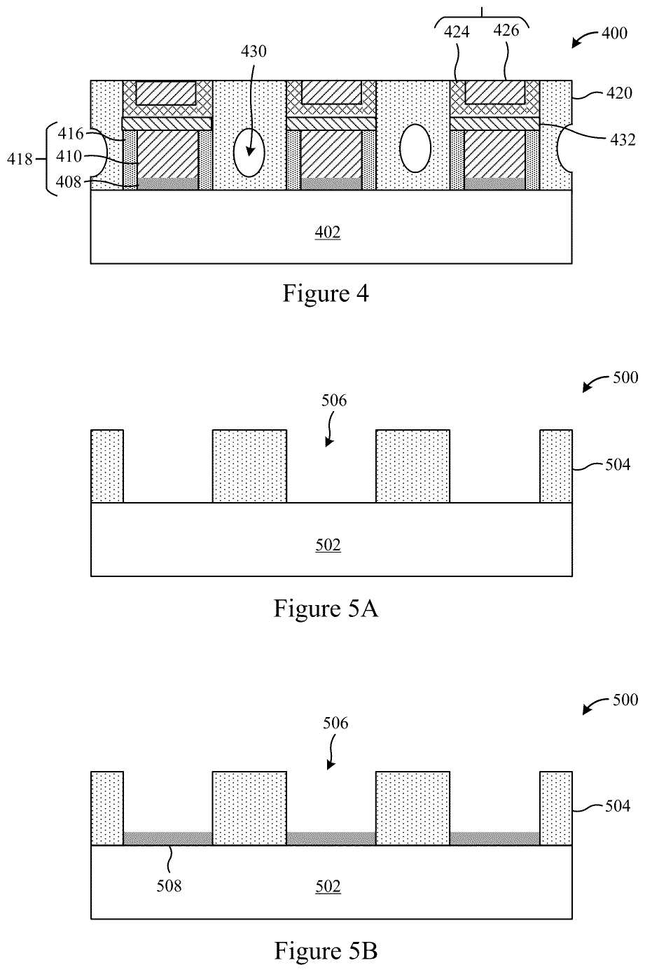

FIG. 4 illustrates a cross-sectional view of a semiconductor structure 400, in accordance with various embodiments. Unless otherwise indicated, features 4xx of FIG. 4 may be similar to features 1xx of FIG. 1M, may be formed using materials and methods that are similar to those described above with reference to FIGS. 1A-1M, and descriptions of the similar features are not repeated herein.

The semiconductor structure 400 represents a variation of the structure shown in FIG. 1M, with the addition of an air gap 430 between adjacent conductive features 418 and a capping layer 432 on top of the conductive features 418. The air gap 430 is formed in the dielectric layer 420 between adjacent conductive features 418, replacing a portion of the solid dielectric material with air or another gas having a lower dielectric constant. This air gap 430 reduces the effective dielectric constant of the material surrounding the conductive features 418, thereby decreasing parasitic capacitance between adjacent conductive features 418.

The capping layer 432 may be selectively formed on the top surface of the conductive features 428, providing enhanced protection against oxidation, electromigration, and other reliability concerns. In some embodiments, the capping layer 432 may be formed before forming a mask layer over the conductive features 418 (see FIGS. 1D and 1E). In various embodiments, the capping layer 432 may comprise materials such as cobalt, ruthenium, tantalum, or other suitable metals or alloys that can enhance the reliability of the conductive features. The capping layer 432 may be formed using selective deposition techniques such as electroless plating, selective CVD, or the like.

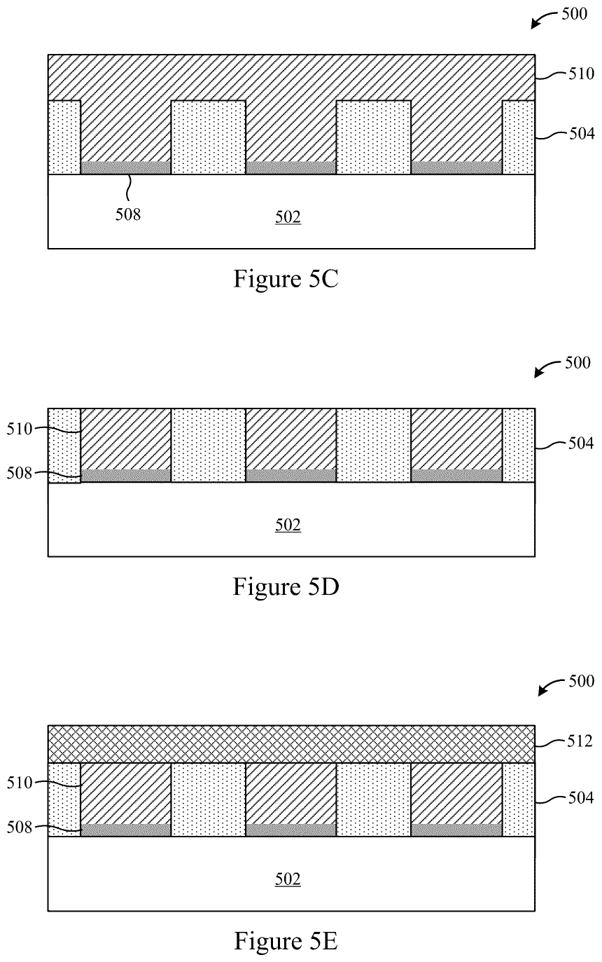

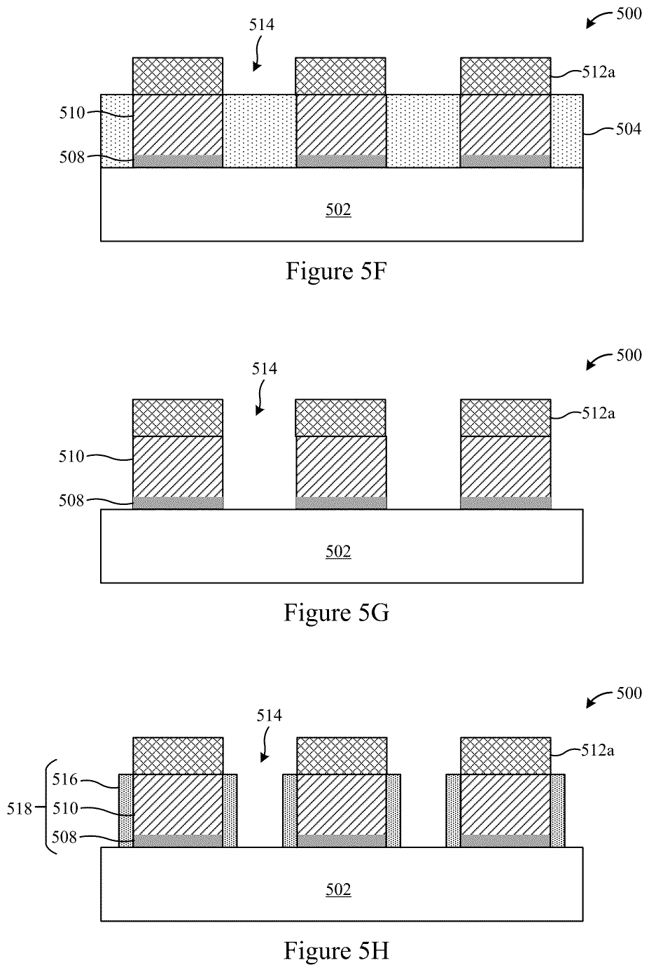

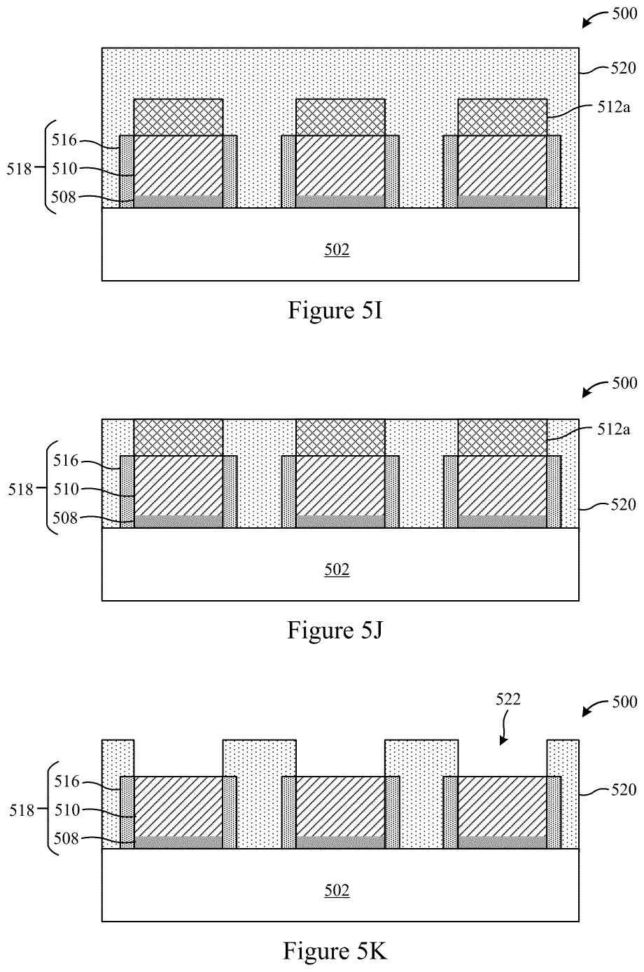

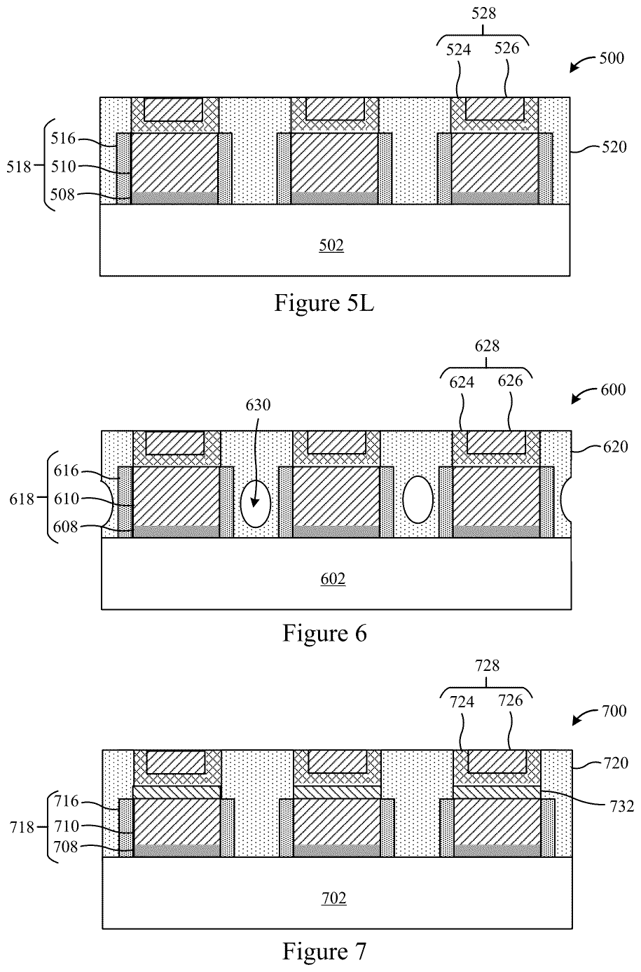

FIGS. 5A-5L illustrate cross-sectional views of intermediate stages in the manufacturing of a semiconductor structure 500, in accordance with various embodiments. Unless otherwise indicated, features 5xx of FIGS. 5A-5L may be similar to features 1xx of FIGS. 1A-1M, may be formed using materials and methods that are similar to those described above with reference to FIGS. 1A-1M, and descriptions of the similar features are not repeated herein. Referring to FIG. 5A, the semiconductor structure 500 includes a substrate 502 with a dielectric layer 504 formed thereon. The dielectric layer 504 has openings 506 formed therein.

Referring to FIG. 5B, a liner layer 508 is selectively deposited on bottoms of the openings 506 leaving sidewalls of the openings 506 substantially free from a material of the liner layer 508. The thickness of the liner layer 508 may be controlled to balance barrier and vertical resistance properties with the available volume for subsequent conductive material filling. In an embodiment, the thickness of the liner layer 508 may be in a range from 1 nm to 5 nm.

Referring to FIG. 5C, a conductive layer 510 is formed over the liner layer 508. The conductive layer 510 fills the openings 506 (see FIG. 5A) in the dielectric layer 504. The conductive layer 610 forms the main current-carrying portion of the interconnect structure.

In some embodiments, the conductive layer 510 may overfill the openings 506 (see FIG. 5A), creating a continuous layer over the top surface of the dielectric layer 504. This excess material will be removed in a subsequent planarization step to form isolated conductive features. The combination of the liner layer 508 and the conductive layer 510 within the openings 506 forms the basis for the interconnect structures that will provide electrical connections within the semiconductor structure 500.

Referring to FIG. 5D, a planarization process may be performed to remove excess portions of the conductive layer 510 and liner layer 508 from the top surface of the dielectric layer 504. The planarization process creates isolated conductive features within the openings 506 (see FIG. 5A), with each feature comprising the conductive layer 510 and the underlying liner layer 508. After performing the planarization process, the top surfaces of the conductive layer 510 and dielectric layer 504 are substantially coplanar or level within process variations of the planarization process.

Referring to FIG. 5E, a mask layer 512 is formed over the planarized surface of the structure shown in FIG. 5D. The mask layer 512 may be deposited as a continuous layer covering the top surfaces of the conductive layer 510 and the dielectric layer 504. This mask layer 512 will serve as a hard mask for subsequent processing steps to enable the self-alignment feature of the disclosed approach. In other embodiments, the mask layer 512 may be selectively deposited only on the conductive layer 510 and not on the dielectric layer 504. Such selective deposition can simplify subsequent processing by eliminating the need for a separate patterning step. In an embodiment, a thickness of the mask layer 512 may be 15 nm or less.

Referring to FIG. 5F, the mask layer 512 is patterned to form patterned mask features 512a and openings 514. The patterning process removes portions of the mask layer 512 that were covering the dielectric layer 504 while leaving the portions covering the conductive layer 510 intact. This creates the patterned mask features 512a that are aligned with respective portions of the underlying conductive layer 510, and openings 514 that expose portions of the dielectric layer 504 between adjacent portions of the conductive layer 510.

The openings 514 define the regions where the dielectric layer 504 will be selectively removed in subsequent processing steps. The width of the openings 514 may be controlled through the lithography and etching processes to achieve the desired spacing between adjacent conductive features. In an embodiment, the patterning may be performed with a slight overlay tolerance, as the self-alignment mechanism of the disclosed approach can accommodate minor misalignments. The patterned mask features 512a will serve as protective caps for the respective portions of the underlying conductive layer 510 during subsequent processing steps, while the openings 514 provide access for the selective removal of the dielectric layer 504.

Referring to FIG. 5G, the dielectric layer 504 is selectively removed through the openings 514. The selective removal process extends the openings 514 into the regions previously occupied by the dielectric layer 504, exposing the sidewalls of the conductive layer 510. The patterned mask features 512a protect the top surfaces of the conductive layer 510 during the removal process. The exposed sidewalls of the conductive layer 510 within the openings 514 provide access for subsequent processing steps, which may include a deposition of a barrier material as described below in greater detail.

Referring to FIG. 5H, a barrier layer 516 is deposited on exposed sidewalls of the conductive layer 510. In an embodiment, a thickness of the barrier layer 516 may be less than 3 nm. In some embodiments, the thickness of the barrier layer 516 may be different from the thickness of the liner layer 508. In one embodiment, the thickness of the barrier layer 516 is less than the thickness of the liner layer 508. In another embodiment, the thickness of the barrier layer 516 is greater than the thickness of the liner layer 508. The patterned mask features 512a protect the top surfaces of the conductive layer 510 during the deposition process. In an embodiment, the liner layer 508 is less electrically resistive than the barrier layer 516. The conductive layer 510, in combination with the barrier layer 516 and the liner layer 508, forms a plurality of conductive features 518 over the substrate 502. The conductive features 518 may be conductive lines, conductive vias, or a combination thereof.

Referring to FIG. 5I, a dielectric layer 520 is formed over the structure shown in FIG. 5H. The dielectric layer 520 fills the openings 514 (see FIG. 5H) and covers the barrier layer 516, which lines the sidewalls of the conductive layer 510. In some embodiments, the dielectric layer 520 overfills the openings 514 and covers top surfaces of the patterned mask features 512a. The dielectric layer 520 provides electrical isolation between the conductive features 518 and forms the foundation for subsequent interconnect layers. Unlike the dielectric layer 504 (see FIG. 5A), which was removed in previous steps, the dielectric layer 520 can be selected specifically for its electrical and mechanical properties without being constrained by compatibility with the initial fabrication steps. This flexibility in material selection allows for optimization of the dielectric properties in the final structure.

Referring to FIG. 5J, a planarization process is performed on the dielectric layer 520 to expose the top surfaces of the patterned mask features 512a. The planarization process creates a planar surface where the top surfaces of the patterned mask features 512a and the remaining portions of the dielectric layer 520 are substantially coplanar or level within process variations of the planarization process. This planarized structure provides a foundation for the subsequent removal of the patterned mask features 512a, which will create recesses for forming self-aligned conductive features in the next interconnect layer. The planar surface also allows for accurate lithography for any additional patterning steps that may be needed.

Referring to FIG. 5K, the patterned mask features 512a (see FIG. 5J) are selectively removed creating openings 522 in the dielectric layer 520. The openings 522 are self-aligned with the underlying conductive features 518. In some embodiments, the selective removal process leaves the dielectric layer 520 intact while completely removing the patterned mask features 512a. The openings 522 created by the removal of the patterned mask features 512a (see FIG. 5J) serve as self-aligned recesses for subsequent formation of conductive features in the next interconnect layer. This self-alignment mechanism allows for eliminating the need for precise lithographic alignment between successive interconnect layers. The dimensions of the openings 522, particularly their depth, are determined by the original thickness of the patterned mask features 512a, which can be controlled during the earlier deposition process. The self-aligned openings 522 ensure improved contact between the current interconnect layer and the next layer to be formed, reducing contact resistance and improving overall device performance.

Referring to FIG. 5L, conductive features 528 are formed in the openings 522 (see FIG. 5K). The conductive features 528 include a barrier layer 524 lining the sidewalls and bottom of each opening 522, and a conductive layer 526 filling the remaining volume of each opening 522. The conductive features 528 that provide electrical connections to the underlying conductive features 518. The thickness of the barrier layer 524 may be optimized to provide sufficient barrier properties while maximizing the volume available for the conductive layer 526. After deposition of the barrier layer 524 and the conductive layer 526, a planarization process such as CMP may be performed to remove excess material and create isolated conductive features 528. The resulting structure features self-aligned conductive features 528 that connect to the underlying conductive features 518. This configuration allows for improving both barrier properties and vertical conductivity.

FIG. 6 illustrates a cross-sectional view of a semiconductor structure 600, in accordance with various embodiments. Unless otherwise indicated, features 6xx of FIG. 6 may be similar to features 5xx of FIG. 5L, may be formed using materials and methods that are similar to those described above with reference to FIGS. 5A-5L, and descriptions of the similar features are not repeated herein.

The semiconductor structure 600 represents a variation of the structure shown in FIG. 5L, with the addition of an air gap 630 between adjacent conductive features 618. The air gap 630 is formed in the dielectric layer 620 between adjacent conductive features 618, replacing a portion of the solid dielectric material of the dielectric layer 620 with air or another gas having a lower dielectric constant. In various embodiments, the air gap 630 may be formed through selective removal of a sacrificial material, controlled deposition techniques that create voids, or other suitable methods. The presence of the air gap 630 reduces the effective dielectric constant of the material surrounding the conductive features 618, thereby decreasing parasitic capacitance between adjacent conductive features 618.

FIG. 7 illustrates a cross-sectional view of a semiconductor structure 700, in accordance with various embodiments. Unless otherwise indicated, features 7xx of FIG. 7 may be similar to features 5xx of FIG. 5L, may be formed using materials and methods that are similar to those described above with reference to FIGS. 5A-5L, and descriptions of the similar features are not repeated herein.

The semiconductor structure 700 represents a variation of the structure shown in FIG. 5L, with the addition of a capping layer 732 on top of the conductive features 718. The capping layer 732 is selectively formed on the top surface of the conductive features 718, providing protection against oxidation, electromigration, and other reliability concerns. In some embodiments, the capping layer 732 may be formed before forming a mask layer over the conductive features 718 (see FIGS. 5D and 5E). In various embodiments, the capping layer 732 may comprise materials such as cobalt, ruthenium, tantalum, or other suitable metals or alloys that can enhance the reliability of the conductive features. The capping layer 732 may be formed using selective deposition techniques such as electroless plating, selective CVD, or the like.

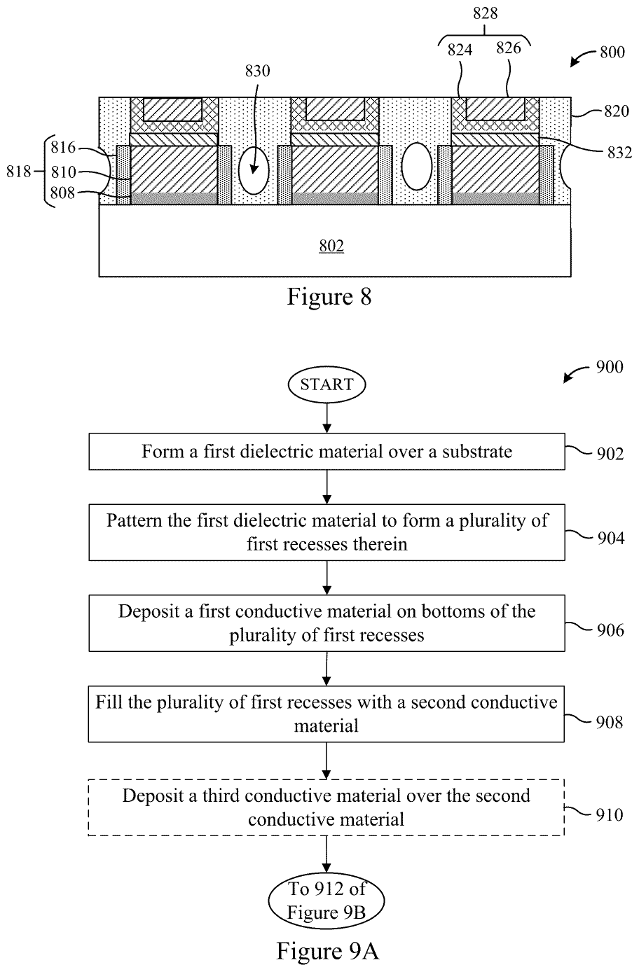

FIG. 8 illustrates a cross-sectional view of a semiconductor structure 800, in accordance with various embodiments. Unless otherwise indicated, features 8xx of FIG. 8 may be similar to features 5xx of FIG. 5L, may be formed using materials and methods that are similar to those described above with reference to FIGS. 5A-5L, and descriptions of the similar features are not repeated herein.

The semiconductor structure 800 represents a variation of the structure shown in FIG. 5L, with the addition of an air gap 830 between adjacent conductive features 818 and a capping layer 832 on top of the conductive features 818. The air gap 830 is formed in the dielectric layer 820 between adjacent conductive features 818, replacing a portion of the solid dielectric material with air or another gas having a lower dielectric constant. This air gap 830 reduces the effective dielectric constant of the material surrounding the conductive features 818, thereby decreasing parasitic capacitance between adjacent conductive features 818.

The capping layer 832 is selectively formed on the top surface of the conductive features 828, providing enhanced protection against oxidation, electromigration, and other reliability concerns. In some embodiments, the capping layer 832 may be formed before forming a mask layer over the conductive features 818 (see FIGS. 5D and 5E). In various embodiments, the capping layer 832 may comprise materials such as cobalt, ruthenium, tantalum, or other suitable metals or alloys that can enhance the reliability of the conductive features. The capping layer 832 may be formed using selective deposition techniques such as electroless plating, selective CVD, or the like.

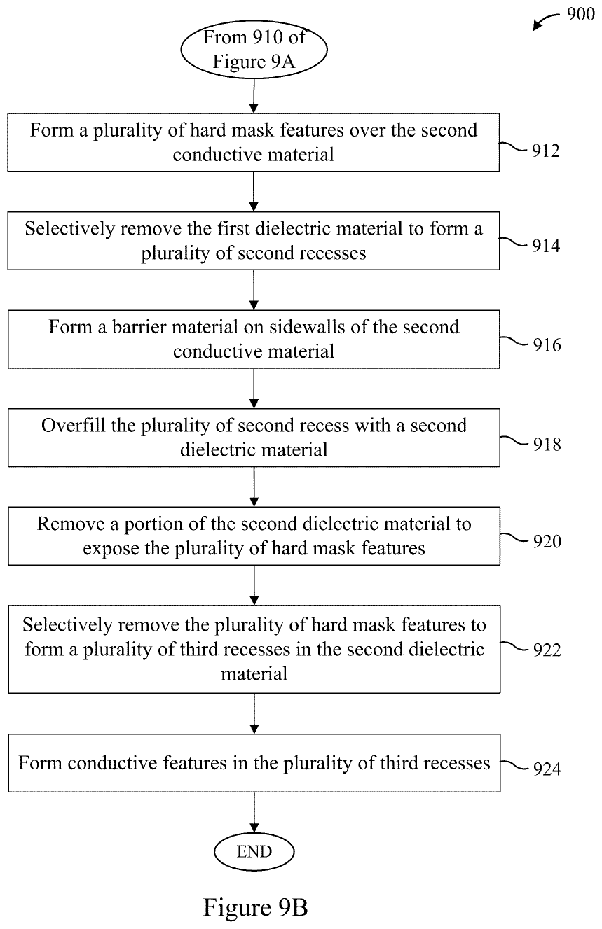

FIGS. 9A and 9B illustrate a flow diagram of a method 900 for forming a semiconductor structure, in accordance with various embodiments. Although shown in a particular sequence, it should be appreciated that the steps of the method 900 may be performed in any suitable sequence.

The method 900 starts with step 902 when a first dielectric material (e.g., dielectric layer 104 of FIG. 1A or dielectric layer 504 of FIG. 5A) is formed over a substrate (e.g., substrate 102 of FIG. 1A or substrate 502 of FIG. 5A) as described above with reference to FIG. 1A or 5A. In step 904, the first dielectric material (e.g., dielectric layer 104 of FIG. 1A or dielectric layer 504 of FIG. 5A) is patterned to form a plurality of first recesses (e.g., openings 106 of FIG. 1A or openings 506 of FIG. 5A) therein as described above with reference to FIG. 1A or 5A.

In step 906, a first conductive material (e.g., liner layer 108 of FIG. 1B or liner layer 508 of FIG. 5B) is deposited on bottoms of the plurality of first recesses (e.g., openings 106 of FIG. 1A or openings 506 of FIG. 5A) as described above with reference to FIG. 1B or 5B. In step 908, the plurality of first recesses (e.g., openings 106 of FIG. 1A or openings 506 of FIG. 5A) are filled with a second conductive material (e.g., conductive layer 110 of FIG. 1C or conductive layer 510 of FIG. 5C) as described above with reference to FIG. 1C or 5C.

In step 910, a third conductive material (e.g., capping layer 332 of FIG. 3, capping layer 432 of FIG. 4, capping layer 732 of FIG. 7, or capping layer 832 of FIG. 8) is deposited over the second conductive material (e.g., conductive layer 310 of FIG. 3, conductive layer 410 of FIG. 4, conductive layer 710 of FIG. 7, or conductive layer 810 of FIG. 8) as described above with reference to FIGS. 3, 4, 7, or 8. In other embodiments, step 910 is optional and may be omitted. In step 912, a plurality of hard mask features (e.g., hard mask features 112a of FIG. 1F or hard mask features 512a of FIG. 5F) are formed over the second conductive material (e.g., conductive layer 110 of FIG. 1C or conductive layer 510 of FIG. 5C) as described above with reference to FIG. 1D-1F or 5D-5F.

In step 914, the first dielectric material (e.g., dielectric layer 104 of FIG. 1F or dielectric layer 504 of FIG. 5F) is selectively removed to form a plurality of second recesses (e.g., openings 114 of FIG. 1G or openings 514 of FIG. 5G) as described above with reference to FIG. 1G or 5G. In step 916, a barrier material (e.g., barrier layer 116 of FIG. 1H or barrier layer 516 of FIG. 5H) is formed on sidewalls of the second conductive material (e.g., conductive layer 110 of FIG. 1H or conductive layer 510 of FIG. 5H) as described above with reference to FIG. 1H, 1I or 5H.

In step 918, the plurality of second recesses (e.g., openings 114 of FIG. 1H or openings 514 of FIG. 5H) are overfilled with a second dielectric material (e.g., dielectric layer 120 of FIG. 1J or dielectric layer 520 of FIG. 5I) as described above with reference to FIG. 1J or 5I. In step 920, a portion of the second dielectric material (e.g., dielectric layer 120 of FIG. 1J or dielectric layer 520 of FIG. 5I) is removed to expose the plurality of hard mask features (e.g., hard mask features 112a of FIG. 1K or hard mask features 512a of FIG. 5J) as described above with reference to FIG. 1K or 5J.

In step 922, the plurality of hard mask features (e.g., hard mask features 112a of FIG. 1K or hard mask features 512a of FIG. 5J) are selectively removed to form a plurality of third recesses (e.g., openings 122 of FIG. 1L or openings 522 of FIG. 5K) in the second dielectric material (e.g., dielectric layer 120 of FIG. 1L or dielectric layer 520 of FIG. 5K) as described above with reference to FIG. 1L or 5K. In step 924, conductive features (e.g., conductive features 128 of FIG. 1M or conductive features 528 of FIG. 5L) are formed in the plurality of third recesses (e.g., openings 122 of FIG. 1L or openings 522 of FIG. 5K) as described above with reference to FIG. 1M or 5L.

Example embodiments of the disclosure are described below. Other embodiments can also be understood from the entirety of the specification as well as the claims filed herein.

Example 1. A semiconductor device including: a dielectric layer over a substrate; and a conductive feature embedded in the dielectric layer, the conductive feature including: a conductive material; a barrier layer extending along a sidewall of the conductive material, the barrier layer including a first material; and a liner extending along a bottom of the conductive material, the liner including a second material different from the first material.

Example 2. The semiconductor device of example 1, where the second material is less electrically resistive than the first material.

Example 3. The semiconductor device of any of examples 1 and 2, where a height of the conductive feature is less than a thickness of the dielectric layer.

Example 4. The semiconductor device of any of examples 1 to 3, further including a void in the dielectric layer adjacent the barrier layer.

Example 5. The semiconductor device of any of examples 1 to 4, where the first material includes a two-dimensional (2D) transition metal dichalcogenide, a metal nitride, or a metal oxide.

Example 6. The semiconductor device of any of examples 1 to 5, where a thickness of the barrier layer is different from a thickness of the liner.

Example 7. A method including: forming a first dielectric layer over a substrate; forming a first recess and a second recess in the first dielectric layer; forming a liner on bottoms of the first recess and the second recess; filling the first recess and the second recesses with a conductive material; forming a first hard mask feature over the conductive material in the first recess; forming a second hard mask feature over the conductive material in the second recess; selectively removing the first dielectric layer to form a third recesses, the third recesses being interposed between the first hard mask feature and the second hard mask feature; forming a barrier layer on sidewalls of the conductive material; forming a second dielectric layer over the conductive material, the second dielectric layer overfilling the third recess; exposing the first hard mask feature and the second hard mask feature; and selectively removing the first hard mask feature and the second hard mask feature to form a fourth recess and a fifth recess in the second dielectric layer.

Example 8. The method of example 7, further including: forming a first conductive feature in the fourth recess; and forming a second conductive feature in the fifth recess.

Example 9. The method of any of examples 7 and 8, where: forming the liner on the bottoms of the first recess and the second recess further includes forming the liner on sidewalls of the first recess and the second recess; and forming the barrier layer on the sidewalls of the conductive material includes converting a portion of the liner formed on the sidewall of the first recess and the second recess into the barrier layer.

Example 10. The method of any of examples 7 to 9, where: forming the liner on sidewalls of the first recess and the second recess includes depositing a transition metal material; and converting the portion of the liner formed on the sidewall of the first recess and the second recess into the barrier layer includes converting the transition metal material into a transition metal dichalcogenide material.

Example 11. The method of any of examples 7 to 10, where: forming the liner on the bottoms of the first recess and the second recess further includes forming the liner on sidewalls of the first recess and the second recess; and forming the barrier layer on the sidewalls of the conductive material includes: removing a portion of the liner from the sidewalls of the conductive material; and depositing the barrier layer on the sidewalls of the conductive material.

Example 12. The method of any of examples 7 to 11, where a material of the barrier layer is different from a material of the liner.

Example 13. The method of any of examples 7 to 12, where the barrier layer includes a two-dimensional (2D) transition metal dichalcogenide, a metal nitride, or a metal oxide.

Example 14. The method of any of examples 7 to 13, where: forming the liner on the bottoms of the first recess and the second recess further includes selectively forming the liner on the bottoms of the first recess and the second recess; and forming the barrier layer on the sidewalls of the conductive material includes depositing the barrier layer on the sidewalls of the conductive material.

Example 15. The method of any of examples 7 to 14, where forming the first hard mask feature over the conductive material in the first recess and forming the second hard mask feature over the conductive material in the second recess includes: selectively depositing the first hard mask feature over the conductive material in the first recess; and selectively depositing the second hard mask feature over the conductive material in the second recess.

Example 16. The method of any of examples 7 to 15, where forming the first hard mask feature over the conductive material in the first recess and forming the second hard mask feature over the conductive material in the second recess includes: blanket depositing a hard mask layer over the first dielectric layer and the conductive material; and patterning the hard mask layer to expose a portion of the first dielectric layer interposed between the first recess and the second recess.

Example 17. A method including: depositing a first dielectric material over a substrate; patterning the first dielectric material to form a plurality of first recesses in the first dielectric material; depositing a first conductive material on bottoms of the plurality of first recesses; filling the plurality of first recesses with a second conductive material; forming a plurality of hard mask features over the second conductive material; selectively removing the first dielectric material to form a plurality of second recesses; forming a barrier layer on sidewalls of the second conductive material; depositing a second dielectric material over the second conductive material, the second dielectric material overfilling the plurality of second recesses; removing a portion of second dielectric material to expose the plurality of hard mask features; and selectively removing the plurality of hard mask features to form a plurality of third recesses in the second dielectric material.

Example 18. The method of example 17, where: depositing the first conductive material on the bottoms of the plurality of first recesses further includes forming the first conductive material on sidewalls of plurality of first recesses; and forming the barrier layer on the sidewalls of the conductive material includes converting a portion of the first conductive material formed on the sidewalls of the plurality of first recesses into a material of the barrier layer.

Example 19. The method of any of examples 17 and 18, where: depositing the first conductive material on the bottoms of the plurality of first recesses further includes forming the first conductive material on sidewalls of plurality of first recesses; and forming the barrier layer on the sidewalls of the conductive material includes: removing a portion of the first conductive material from the sidewalls of the conductive material; and depositing a material of the barrier layer on the sidewalls of the conductive material.

Example 20. The method of any of examples 17 to 19, where: depositing the first conductive material on the bottoms of the plurality of first recesses includes selectively forming the first conductive material on the bottoms of the plurality of first recesses; and forming the barrier layer on the sidewalls of the conductive material includes depositing a material of the barrier layer on the sidewalls of the conductive material.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present disclosure can be embodied and viewed in many different ways.

“Substrate,” “target substrate,” “structure,” or “device” as used herein generically refers to an object being processed in accordance with the disclosure, and may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate, structure, or device is not limited to any particular base structure, underlying layer or overlying layer, patterned or un-patterned, but rather, is contemplated to include any such layer or base structure, and any combination of layers and/or base structures. The description may reference particular types of substrates, structures, or devices, but this is for illustrative purposes only.

Although this disclosure describes particular process steps as occurring in a particular order, this disclosure contemplates the process steps occurring in any suitable order. While this disclosure has been described with reference to illustrative embodiments, this description is not intended to be construed in a limiting sense. Various modifications and combinations of the illustrative embodiments, as well as other embodiments of the disclosure, will be apparent to persons skilled in the art upon reference to the description. It is therefore intended that the appended claims encompass any such modifications or embodiments.

What is claimed is:

1. A semiconductor device comprising:
a dielectric layer over a substrate; and
a conductive feature embedded in the dielectric layer, the conductive feature comprising:
a conductive material;
a barrier layer extending along a sidewall of the conductive material, the barrier layer comprising a first material; and
a liner extending along a bottom of the conductive material, the liner comprising a second material different from the first material.

2. The semiconductor device of claim 1, wherein the second material is less electrically resistive than the first material.

3. The semiconductor device of claim 1, wherein a height of the conductive feature is less than a thickness of the dielectric layer.

4. The semiconductor device of claim 1, further comprising a void in the dielectric layer adjacent the barrier layer.

5. The semiconductor device of claim 1, wherein the first material comprises a two-dimensional (2D) transition metal dichalcogenide, a metal nitride, or a metal oxide.

6. The semiconductor device of claim 1, wherein a thickness of the barrier layer is different from a thickness of the liner.

7. A method comprising:
forming a first dielectric layer over a substrate;
forming a first recess and a second recess in the first dielectric layer;
forming a liner on bottoms of the first recess and the second recess;
filling the first recess and the second recesses with a conductive material;
forming a first hard mask feature over the conductive material in the first recess;
forming a second hard mask feature over the conductive material in the second recess;
selectively removing the first dielectric layer to form a third recesses, the third recesses being interposed between the first hard mask feature and the second hard mask feature;
forming a barrier layer on sidewalls of the conductive material;
forming a second dielectric layer over the conductive material, the second dielectric layer overfilling the third recess;
exposing the first hard mask feature and the second hard mask feature; and
selectively removing the first hard mask feature and the second hard mask feature to form a fourth recess and a fifth recess in the second dielectric layer.

8. The method of claim 7, further comprising:
forming a first conductive feature in the fourth recess; and
forming a second conductive feature in the fifth recess.

9. The method of claim 7, wherein:
forming the liner on the bottoms of the first recess and the second recess further comprises forming the liner on sidewalls of the first recess and the second recess; and
forming the barrier layer on the sidewalls of the conductive material comprises converting a portion of the liner formed on the sidewall of the first recess and the second recess into the barrier layer.

10. The method of claim 9, wherein:
forming the liner on sidewalls of the first recess and the second recess comprises depositing a transition metal material; and
converting the portion of the liner formed on the sidewall of the first recess and the second recess into the barrier layer comprises converting the transition metal material into a transition metal dichalcogenide material.

11. The method of claim 7, wherein:
forming the liner on the bottoms of the first recess and the second recess further comprises forming the liner on sidewalls of the first recess and the second recess; and
forming the barrier layer on the sidewalls of the conductive material comprises:
removing a portion of the liner from the sidewalls of the conductive material; and
depositing the barrier layer on the sidewalls of the conductive material.

12. The method of claim 11, wherein a material of the barrier layer is different from a material of the liner.

13. The method of claim 11, wherein the barrier layer comprises a two-dimensional (2D) transition metal dichalcogenide, a metal nitride, or a metal oxide.

14. The method of claim 7, wherein:
forming the liner on the bottoms of the first recess and the second recess further comprises selectively forming the liner on the bottoms of the first recess and the second recess; and
forming the barrier layer on the sidewalls of the conductive material comprises depositing the barrier layer on the sidewalls of the conductive material.

15. The method of claim 7, wherein forming the first hard mask feature over the conductive material in the first recess and forming the second hard mask feature over the conductive material in the second recess comprises:
selectively depositing the first hard mask feature over the conductive material in the first recess; and
selectively depositing the second hard mask feature over the conductive material in the second recess.

16. The method of claim 7, wherein forming the first hard mask feature over the conductive material in the first recess and forming the second hard mask feature over the conductive material in the second recess comprises:
blanket depositing a hard mask layer over the first dielectric layer and the conductive material; and
patterning the hard mask layer to expose a portion of the first dielectric layer interposed between the first recess and the second recess.

17. A method comprising:
depositing a first dielectric material over a substrate;
patterning the first dielectric material to form a plurality of first recesses in the first dielectric material;
depositing a first conductive material on bottoms of the plurality of first recesses;
filling the plurality of first recesses with a second conductive material;
forming a plurality of hard mask features over the second conductive material;
selectively removing the first dielectric material to form a plurality of second recesses;
forming a barrier layer on sidewalls of the second conductive material;
depositing a second dielectric material over the second conductive material, the second dielectric material overfilling the plurality of second recesses;
removing a portion of second dielectric material to expose the plurality of hard mask features; and
selectively removing the plurality of hard mask features to form a plurality of third recesses in the second dielectric material.

18. The method of claim 17, wherein:
depositing the first conductive material on the bottoms of the plurality of first recesses further comprises forming the first conductive material on sidewalls of plurality of first recesses; and
forming the barrier layer on the sidewalls of the conductive material comprises converting a portion of the first conductive material formed on the sidewalls of the plurality of first recesses into a material of the barrier layer.

19. The method of claim 17, wherein:
depositing the first conductive material on the bottoms of the plurality of first recesses further comprises forming the first conductive material on sidewalls of plurality of first recesses; and
forming the barrier layer on the sidewalls of the conductive material comprises:
removing a portion of the first conductive material from the sidewalls of the conductive material; and
depositing a material of the barrier layer on the sidewalls of the conductive material.

20. The method of claim 17, wherein:
depositing the first conductive material on the bottoms of the plurality of first recesses comprises selectively forming the first conductive material on the bottoms of the plurality of first recesses; and
forming the barrier layer on the sidewalls of the conductive material comprises depositing a material of the barrier layer on the sidewalls of the conductive material.
